(19) United States
(12) Patent Application Publication
(10) Pub. No.: US 2024/0119187 A1
(43) Pub. Date: Apr. 11, 2024

(54) System and Method for Field Capture of Safety Lifecycle Management Services Data

(71) Applicant: Open Range Applications, Inc., Pampa, TX (US)

(72) Inventors: Dan Miller, Pampa, TX (US); Ronald Nelson, Pampa, TX (US)

(21) Appl. No.: 18/296,989

(22) Filed: Apr. 6, 2023

Related U.S. Application Data
(60) Provisional application No. 63/362,550, filed on Apr. 6, 2022.

(51) Int. Cl. G06F 30/12; G06F 30/18; G06F 40/143

(52) U.S. Cl. CPC G06F 30/12; G06F 30/18; G06F 40/143; G10L 15/26

(57) ABSTRACT

A field data capture system is disclosed. Comprising one or more computers comprising of a first computers having a processor, a memory, a communication hardware and a data storage. said first computers capable of storing and modifying a SLMS data records. a device application stored in said memory and execute in said processor of said first computers. said device application is configured for receiving, modifying and storing as an SLMS data records of an input of one or more starting points, one or more lines, one or more equipment arranged on said one or more lines, and one or more end points. said device application is configured for receiving one or more symbols, analyzing said one or more symbols, displaying a match for said one or more symbols, receiving a confirmation or rejection of said match, receiving one or more variables with said one or more symbols.

### CROSS-REFERENCE TO RELATED APPLICATIONS

This application claims benefit to and incorporates by reference U.S. provisional patent application 63/362,550 filed on 2022 Apr. 6.

### STATEMENT REGARDING FEDERALLY SPONSORED RESEARCH OR DEVELOPMENT (IF APPLICABLE)

Not applicable.

### REFERENCE TO SEQUENCE LISTING, A TABLE, OR A COMPUTER PROGRAM LISTING COMPACT DISC APPENDIX (IF APPLICABLE)

Not applicable.

### BACKGROUND OF THE INVENTION

No prior art is known to the Applicant

### BRIEF SUMMARY OF THE INVENTION

To come.

### BRIEF DESCRIPTION OF THE SEVERAL VIEWS OF THE DRAWING

FIG. 1 illustrates a field data capture system 100.

FIGS. 2A, 2B and 2C illustrate three overviews of exemplary computers, comprising a mobile phone 201a, a personal computer 201b, and a tablet 201c.

FIG. 3 illustrates an SLMS data 206 within one or more computers 102.

FIGS. 4A and 4B illustrate a flow diagram between a first computers 102a and one or more servers 108 and an alternative configuration of said first computers 102a.

FIGS. 5A and 5B illustrate two examples of a flow diagram between a communication hardware 308 of said first computers 102a and a first servers 108a.

FIGS. 6A and 6B illustrate illustrates an elevated front view of said tablet 201c with a rendering of a device application 502 and an isolated view of a SLMS data records 504.

FIGS. 7A-7F illustrate a sequence of renderings by said device application 502 alongside of said SLMS data records 504.

FIG. 7B illustrates a step of adding another valve to a process diagram 600.

FIG. 7C illustrates a step of adding a new split to said process diagram 600.

FIG. 7D illustrates a step of adding another valve below the merged area in said process diagram 600.

FIG. 7E illustrates the steps of adding a seventh equipment 612g.

FIG. 7F illustrates said process diagram 600 fully rendered.

FIG. 7G illustrates a detailed part screen 748 for said seventh equipment 612g.

FIGS. 8A and 8B illustrate two flow diagrams as to how said device application 502 can interpret data entered into a data entry area 602.

FIG. 8A illustrates a plurality of interpreting steps 800.

FIG. 8B illustrates a plurality of diagram creation steps 828.

FIG. 9 illustrates a flow diagram view of a data storage 110 comprising a predefined symbols 902 and a user defined symbols 904.

FIGS. 10A, 10B, 10C, 10D and 10E illustrate a table of symbols 1000.

FIGS. 11A and 11B illustrate a rendered P&ID diagram 1100 and a simplified P&ID diagram 1101 (like said process diagram 600).

FIGS. 12A and 12B illustrate a rendered weld mapping diagram 1200 and a simplified weld mapping diagram 1201 (like said process diagram 600).

FIGS. 13A and 13B illustrate a rendered pipe status diagram 1300 and a simplified pipe status diagram 1301 (like said process diagram 600).

FIGS. 14A and 14B illustrate a rendered PFD diagram 1400 and a simplified PFD diagram 1401 (like said process diagram 600).

FIGS. 15A and 15B illustrate a rendered electrical diagram 1500 and a simplified electrical diagram 1501.

FIG. 16 illustrates a flow diagram for exporting data from said field data capture system 100.

FIGS. 17A and 17B illustrate two elevated overviews of an industrial layout diagram 1700.

FIG. 17B illustrates a portion of said industrial layout diagram 1700 at a stage where a flare vent stack 1722 is being added to a grid 1702.

FIG. 18 illustrates a flow diagram of a plurality of plotting steps 1800.

FIGS. 19A, and 19B illustrate a voice to equipment use scenario 1900 of said field data capture system 100 and a flow chart of matching voice inputs to data in said device application 502.

FIGS. 20A, and 20B illustrate said detailed part screen 748 with a microphone icon 2000.

FIG. 21 illustrates a voice to equipment flow chart 2100.

FIG. 22 illustrates a term and equipment cross reference table 2104 and one or more new matching terms 2102.

FIG. 23 illustrates an equipment data collection diagram 2300.

FIGS. 24A, and 24B illustrate a first image 754a and said first image 754a with one or more hyperlinked zones 2400, respectively.

### DETAILED DESCRIPTION OF THE INVENTION

The following description is presented to enable any person skilled in the art to make and use the invention as claimed and is provided in the context of the particular examples discussed below, variations of which will be readily apparent to those skilled in the art. In the interest of clarity, not all features of an actual implementation are described in this specification. It will be appreciated that in the development of any such actual implementation (as in any development project), design decisions must be made to achieve the designers' specific goals (e.g., compliance with system- and business-related constraints), and that these goals will vary from one implementation to another. It will also be appreciated that such development effort might be complex and time-consuming, but would nevertheless be a routine undertaking for those of ordinary skill in the field of the appropriate art having the benefit of this disclosure. Accordingly, the claims appended hereto are not intended to be limited by the disclosed embodiments, but are to be accorded their widest scope consistent with the principles and features disclosed herein.

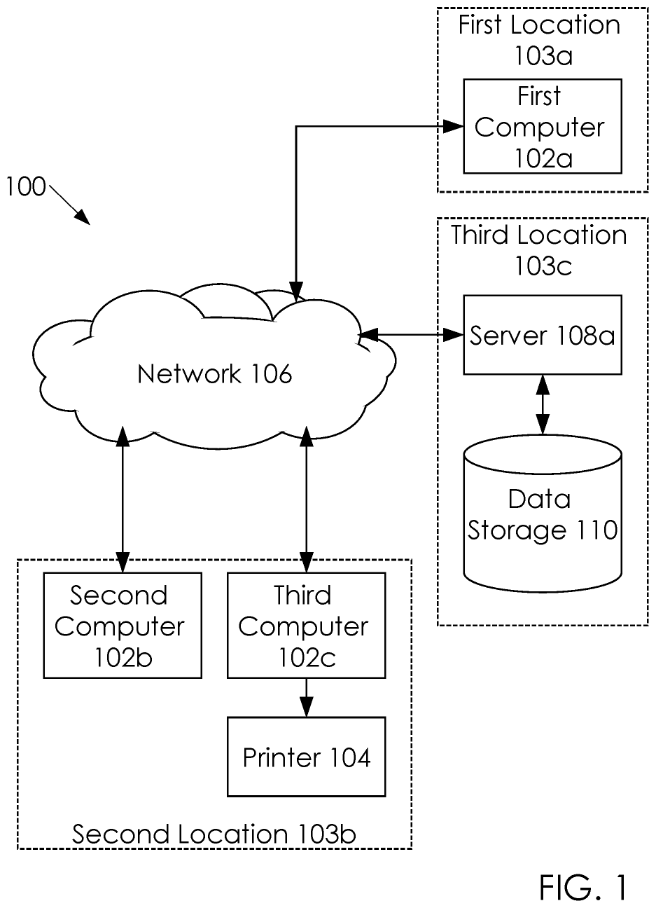

FIG. 1 illustrates a field data capture system 100.

In one embodiment, said field data capture system 100 can comprise one or more computers 102 (which can comprise a first computers 102a, a second computers 102b, and a third computers 102c) at one or more locations 103 (which can comprise a first locations 103a, a second locations 103b, and a third locations 103c).

In one embodiment, said first locations 103a can comprise a field location. In one embodiment, said field data capture system 100 can capture a SLMS data at said field location. In one embodiment, said one or more computers 102 can communicate on a network 106, which can connect to one or more servers 108 (which can comprise a first servers 108a), and a data storage 110. In one embodiment, a printer 104 can be hardwired to said first computers 102a (not illustrated here) or said printer 104 can connect to one of said one or more computers 102 (such as said third computers 102c, illustrated) said network 106.

Said network 106 can be a local (LAN), a wide area (WAN), a piconet, or a combination of LANs, WANs, or piconets. One illustrative LAN is said network 106 within a single business. One illustrative WAN is the Internet.

In one embodiment, said one or more servers 108 represents at least one, but can be many servers, each connected to said network 106. Said one or more servers 108 can connect to said printer 104. Said data storage 110 can connect directly to said one or more servers 108, as shown in FIG. 1, or may exist remotely on said network 106. In one embodiment, said data storage 110 can comprise any suitable long-term or persistent storage device and, further, may be separate devices or the same device and may be collocated or distributed (interconnected via any suitable communications network).

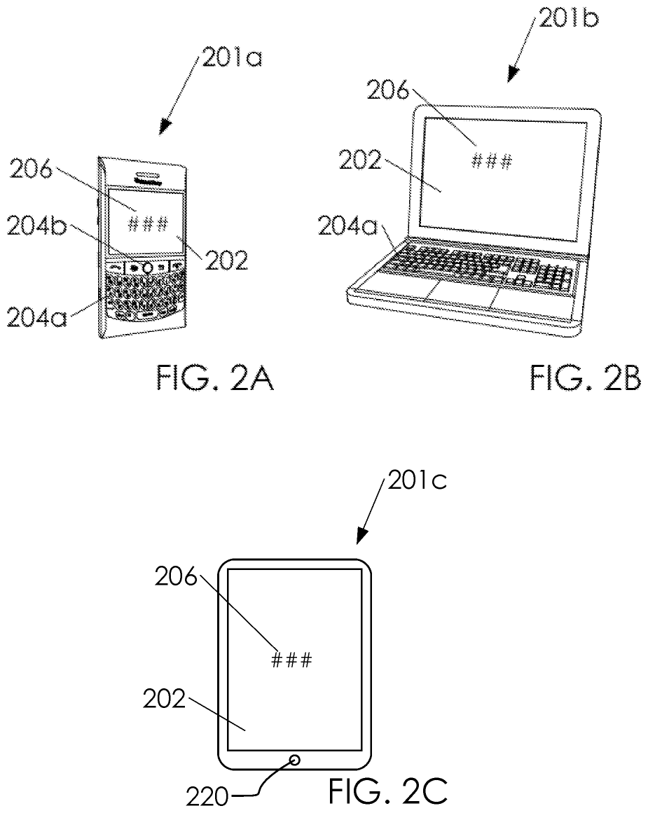

FIGS. 2A, 2B and 2C illustrate three overviews of exemplary computers, comprising a mobile phone 201a, a personal computer 201b, and a tablet 201c.

In the last several years, the useful definition of a computer has become more broadly understood to include mobile phones, tablet computers, laptops, desktops, and similar. In one embodiment, said one or more computers 102 each can include, but is not limited to, a laptop (such as said tablet 201c), desktop, workstation, server, mainframe, terminal, a tablet (such as said tablet 201c), a phone (such as said personal computer 201b), and/or similar. Despite different form-factors, said one or more computers 102 can have similar basic hardware, such as said tablet 201c and one or more input devices 204 (which can comprise a first input devices 204a, a second input devices 204b, a third input devices 204c, and a fourth input devices 204d, RFID reader, and/or a home button 220). In one embodiment, said one or more input devices 204 can comprise a screen 202. In one embodiment, said home button 220 can function similarly to a computer mouse as is known in the art. In one embodiment, said tablet 201c can comprise a Microsoft® Windows® branded device, or similar. In one embodiment, said tablet 201c can be an X86 type processor or an AMD type processor.

Said field data capture system 100 can comprise an SLMS data 206. In one embodiment, said SLMS data 206 can comprise data related to Safety Lifecycle Management Services (hereafter “SLMS”, or “SLMS data”).

In one embodiment, said one or more computers 102 can be used to input and view said SLMS data 206. In one embodiment, said SLMS data 206 can be input into said one or more computers 102 by taking pictures with one of said fourth input devices 204d, by typing in information with said second input devices 204b, or by using gestures on said one or more input devices 204 (where said one or more input devices 204 is a touch screen). Many other data entry means for devices similar to said one or more computers 102 are well known and herein also possible with said SLMS data 206. In one embodiment, said first computers 102a can comprise an iPhone®, a BlackBerry®, a smartphone, or similar. In one embodiment, said one or more computers 102 can comprise a laptop computer, a desktop computer, or similar.

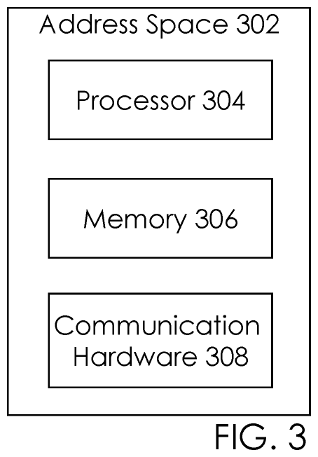

FIG. 3 illustrates said SLMS data 206 within said one or more computers 102.

Each among said one or more computers 102 and said one or more servers 108 can comprise an embodiment of address space 302.

In one embodiment, said one or more computers 102 can comprise said address space 302 defined by a processor 304, a memory 306, and a communication hardware 308. In one embodiment, said memory 306 can comprise a plurality of processors, said communication hardware 308 can comprise a plurality of memory modules, and said communication hardware 308 can comprise a plurality of communication hardware components. In one embodiment, said SLMS data 206 can be sent to said memory 306; wherein, said memory 306 can perform processes on said SLMS data 206 according to an application stored in said communication hardware 308, as discussed further below. Said process can include storing said SLMS data 206 into said communication hardware 308, verifying said SLMS data 206 conforms to one or more preset standards, or ensuring a required set among said required said SLMS data 206 has been gathered for said SLMS data 206 management system and method. In one embodiment, said SLMS data 206 can include data which said one or more computers 102 can populate automatically, such as a date and a time, as well as data entered manually. Once a portion of gathering data has been performed said SLMS data 206 can be sent to said communication hardware 308 for communication over said network 106. Said communication hardware 308 can include said network 106 transport processor for packetizing data, communication ports for wired communication, or an antenna for wireless communication. In one embodiment, said SLMS data 206 can be collected in said one or more computers 102 and delivered to said one or more servers 108 through said network 106.

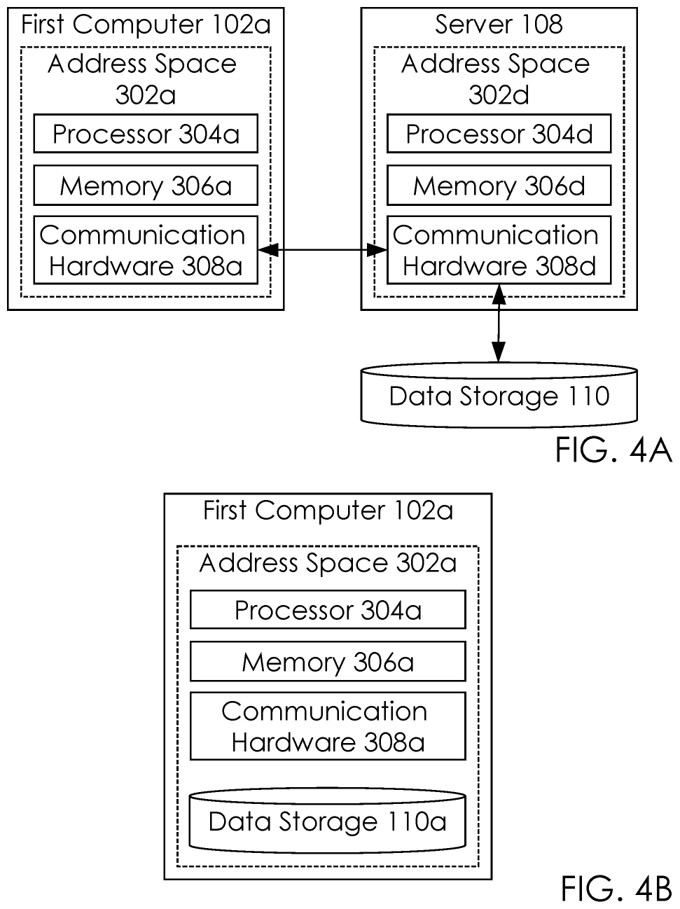

FIGS. 4A and 4B illustrate a flow diagram between said first computers 102a and said one or more servers 108 and an alternative configuration of said first computers 102a.

In one embodiment, both said first computers 102a and said one or more servers 108 can comprise said address space 302 comprising said memory 306, said communication hardware 308 and said communication hardware 308, as illustrated. Wherein, said communication hardware 308 of said one or more computers 102 and said one or more servers 108 can communicate with and another to exchange relevant data.

As illustrated in FIG. 4A, in one embodiment, said one or more servers 108 can comprise a commercial “cloud” service (such as Dropbox®, Microsoft® OneDrive®, AWS®, or similar); wherein, said first computers 102a can pass data back and forth with said one or more servers 108 which can be in a distant location and can possibly be managed by a third-party, as is known in the art. However, said one or more servers 108 can be privately managed as well.

As illustrated in FIG. 4B, said data storage 110 can be located on said first computers 102a. Thus, said first computers 102a can operate without a data connection out to said one or more servers 108 while performing actions within said field data capture system 100.

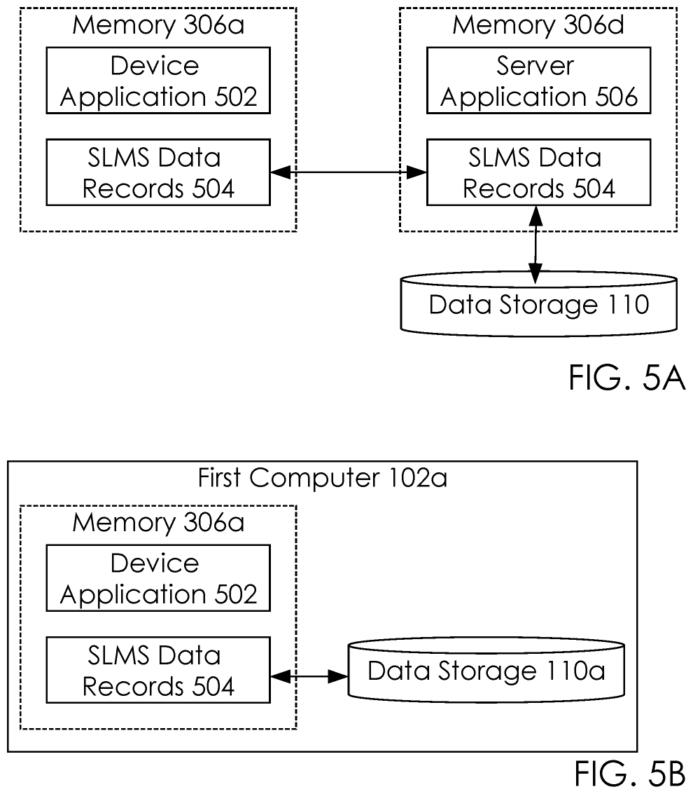

FIGS. 5A and 5B illustrate two examples of a flow diagram between said communication hardware 308 of said first computers 102a and said first servers 108a.

As illustrated in FIG. 5A, in one embodiment, said field data capture system 100 can process said SLMS data 206 on said first computers 102a and/or said one or more servers 108 using a device application 502. For example, in one embodiment, said communication hardware 308 in said first computers 102a can comprise said communication hardware 308 capable of generating a SLMS data records 504 from user inputs or, otherwise, processing said SLMS data records 504 delivered to and from said data storage 110.

In one embodiment, said SLMS data records 504 can be transferred between said one or more computers 102 and said one or more servers 108. In one embodiment, said one or more servers 108 can be useful for processing said SLMS data records 504, as is known in the art. As illustrated in FIG. 5B, in another embodiment, said one or more servers 108 can be removed from the flow diagram entirely as said communication hardware 308 of said first computers 102a is capable of processing said SLMS data records 504 and/or said SLMS data 206 without the assistance of said one or more servers 108. In one embodiment, said SLMS data 206 can comprise data related to and SLMS system; whereas, said SLMS data records 504 can comprise computer data representing said SLMS data 206.

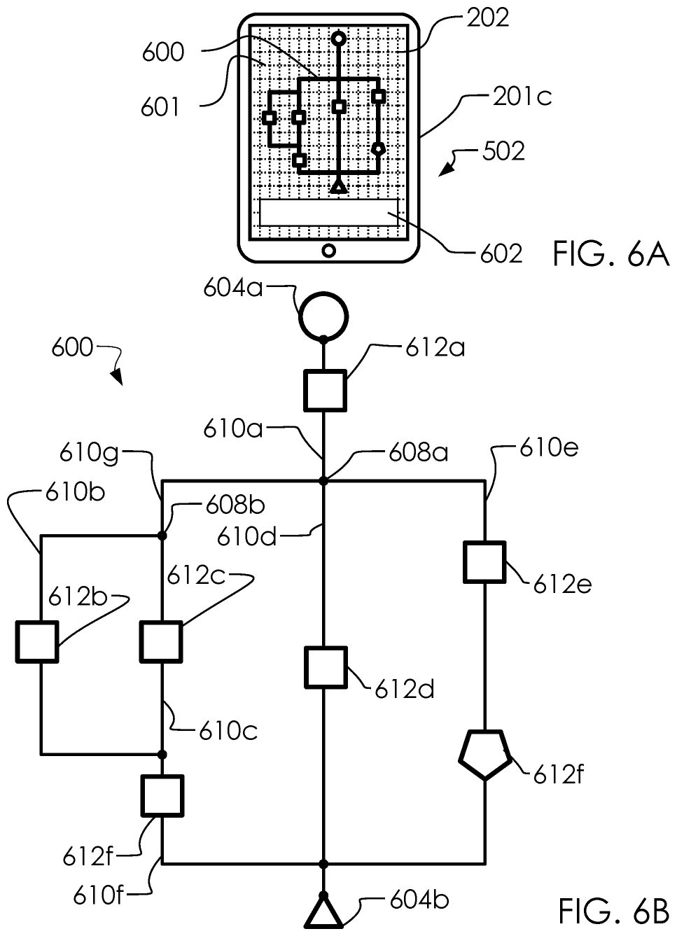

FIGS. 6A and 6B illustrate illustrates an elevated front view of said tablet 201c with a rendering of said device application 502 and an isolated view of said SLMS data records 504.

In one embodiment, said device application 502 can render a process diagram 600 with a grid 601 and a data entry area 602 on said screen 202. In one embodiment, said process diagram 600 can comprise one or more starting points 604a, one or more end points 604b, one or more split points 608, one or more lines 610, and one or more equipment 612.

In one embodiment, said one or more split points 608 can comprise a first split point 608a and a second split point 608b. In one embodiment, said one or more lines 610 can comprise a first line 610a, a second line 610b, a third line 610c, a fourth line 610d, a fifth line 610e, a sixth line 610f, and a seventh line 610g. In one embodiment, said one or more equipment 612 can comprise a first equipment 612a, a second equipment 612b, a third equipment 612c, a fourth equipment 612d, a fifth equipment 612e, a sixth equipment 612f and a seventh equipment 612g. In one embodiment, said data entry area 602 can be used to receive user input into said device application 502, which can thereafter be processed into said one or more equipment 612, said one or more lines 610, or similar, as discussed below.

In one embodiment, said process diagram 600 can be a place holder for many different types of equipment types which can be entered into said field data capture system 100. For example, the principles presented in said process diagram 600 can be used to draw PFD field sketches, P&ID field sketches, Electrical-Instrument field sketches, ultrasonic TML mapping, and weld mapping, as will be discussed below. As an initial exercise, however, this disclosure will limit itself to a block diagram as presented.

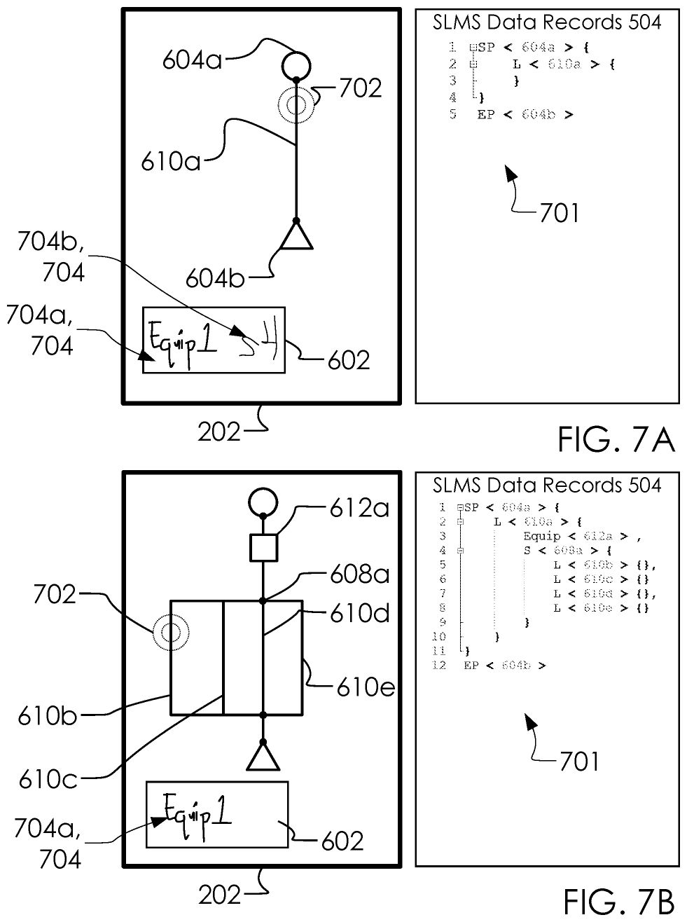

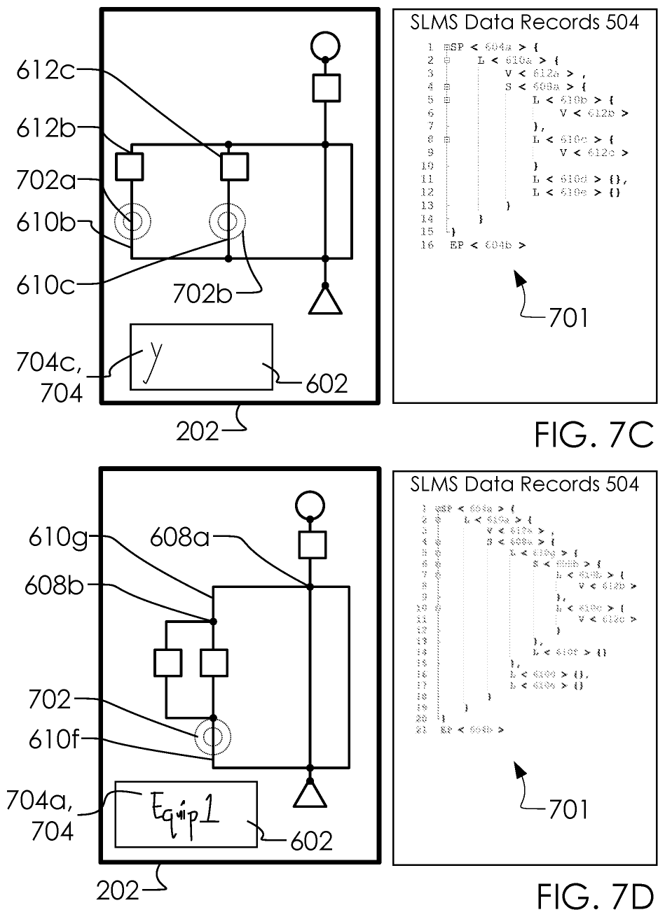

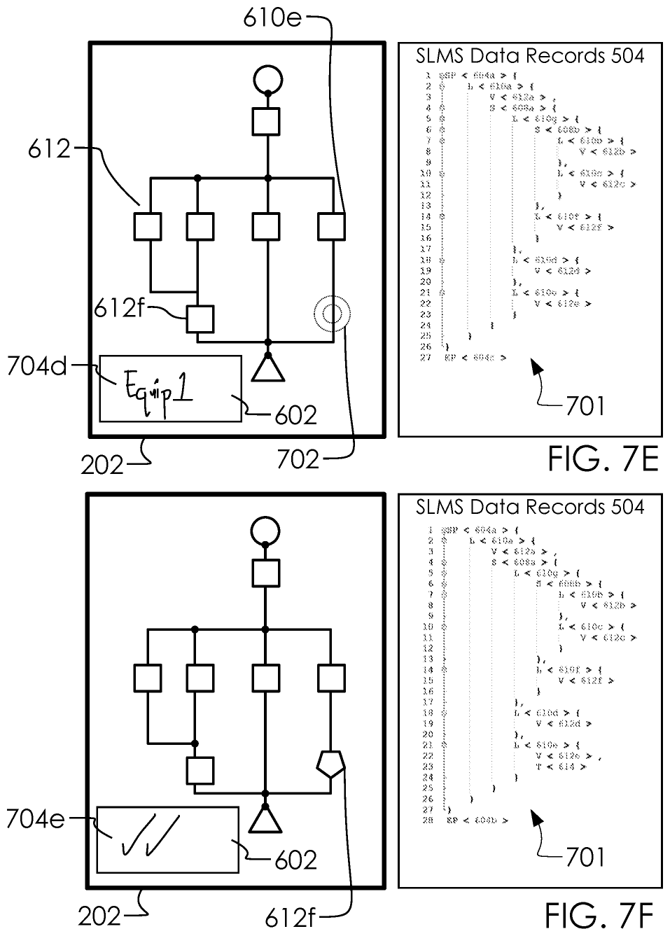

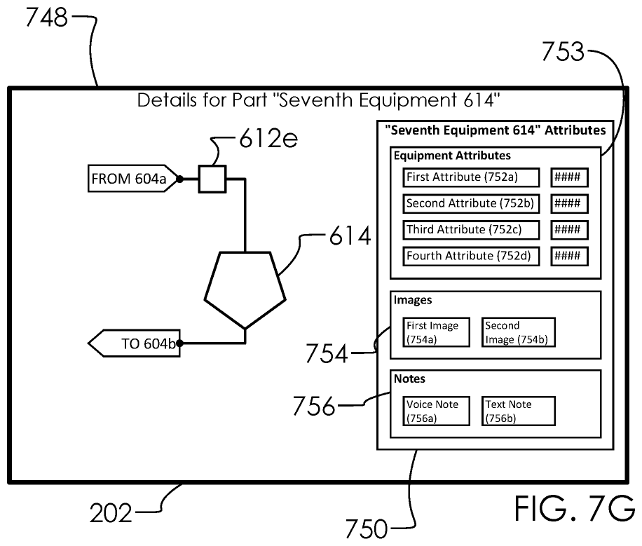

FIGS. 7A-7F illustrate a sequence of renderings by said device application 502 alongside of said SLMS data records 504.

In one embodiment, said SLMS data records 504 can be edited by a user input on said screen 202. In one embodiment, said user input can comprise touch input (as is known in the art for data entry on a tablet, such as said tablet 201c), typed input, spoken input, or similar. Accordingly, said SLMS data records 504 can contain very little data, as the form of said process diagram 600 is quite simple.

In one embodiment, said process diagram 600 can be represented with a structured markup language 701 stored in said SLMS data records 504. In one embodiment, said structured markup language 701 can comprise a function, an identifier and one or more sub-functions. For example, in one embodiment, said one or more starting points 604a can be represented in said structured markup language 701 as “SP<604>{ . . . }”, where said “SP” comprise a starting point function, said “604” comprises a number useful as said identifier, and said “ . . . ” represents said one or more sub-functions, which are omitted here for brevity. In one embodiment, said structured markup language 701 can comprise “L” as a line function, “EP” as an end point function, “Equip1” and “Equip2” as equipment functions, “V” as a valve function, “S” as a split function, and “T” as a tank function. Additionally, each among said functions can comprise attributes. For example, in one embodiment, valve number 99 can comprise attributes “FV”, “FY” and “FC” (as are known in the art), which would cause it to be represented as “V<99><FV, FY, FC>” in said structured markup language 701. In another embodiment, said attributes of said equipment can be stored in a separate table with unique identifiers referring back to said structured markup language 701. Other functions will be obvious to one in the art, and will be presented below as necessary. As is common in the art of markup language, such as HTML and XLM, line breaks are to be disregarded. FIGS. 7A-7E layout said screen 202 and said SLMS data records 504 next to one another as a sample of how said SLMS data records 504 are created and modified as said structured markup language 701, and how said SLMS data records 504 are rendered on said screen 202.

Turning to FIG. 7A, in one embodiment, said process diagram 600 can begin with only said one or more starting points 604a and said one or more end points 604b, each connected to one another by said first line 610a. In one embodiment, said one or more starting points 604a can be rendered as a circle and said one or more end points 604b can be rendered as a triangle, but these representations are not necessarily the only proper renderings of these parts of said process diagram 600. In one embodiment, said process diagram 600 can comprise a plurality of either or both of said one or more starting points 604a and said one or more end points 604b, as illustrated infra.

In one embodiment, said process diagram 600 can be modified by: touching said process diagram 600 on said screen 202 at a touch point 702, and entering one or more symbols 704 in said data entry area 602. Examples of said one or more symbols 704 can comprise a first equipment symbolb 704a, a split and number symbol 704b, a merger symbol 704c, a tank symbol 704d, and a finished symbol 704e.

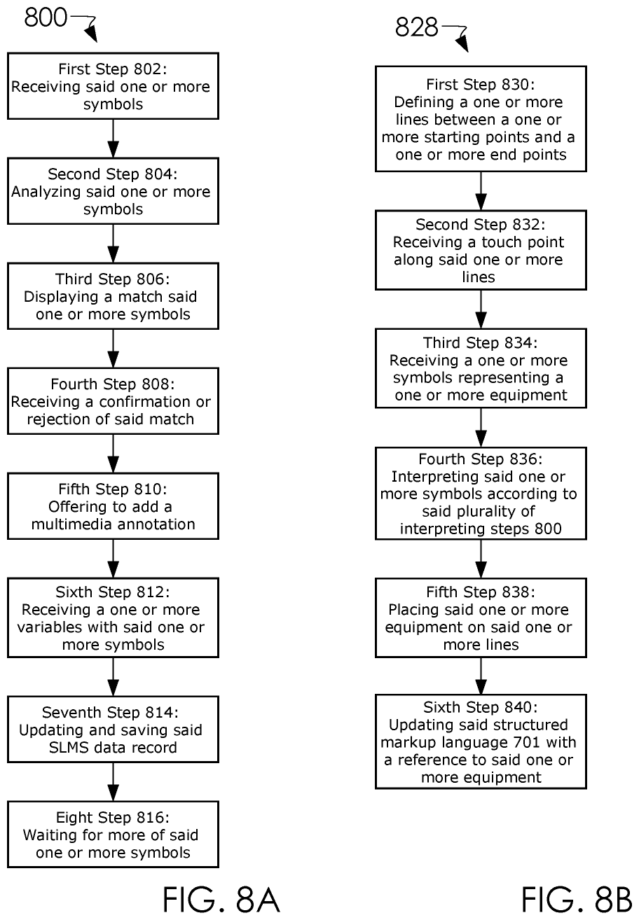

In one embodiment, said one or more symbols can be interpreted by said device application 502 and rendered as said structured markup language 701 and used to update said process diagram 600. For example, in one embodiment, a user can touch said first line 610a with said touch point 702 and enter said first equipment symbolb 704a (representing said one or more equipment) followed by said split and number symbol 704b. In one embodiment, entering said one or more symbols 704 (such as said first equipment symbolb 704a and said split and number symbol 704b) can be entered into said data entry area 602 can cause said field data capture system 100 to translate said one or more symbols 704 and place them on said process diagram 600. In one embodiment, said first equipment symbolb 704a can comprise a complete text or abbreviated text version of the equipment to be drawn; for example, a screwed ball valve can be established by writing “BAL”. Likewise, a diagram can be used rather than a text input. Note, however, that said process diagram 600 is a placeholder for a more complex diagram to be described below. In one embodiment, “translating said one or more symbols 704” can comprise said field data capture system 100 comparing data entered into said data entry area 602 to a database in said data storage 110 comprising of a predefined symbols 902 (not illustrated here, discussed below) and a user defined symbols 904 (not illustrated here, discussed below). A method for translating said one or more symbols 704 is discussed and illustrated in FIG. 8, below.

Here, said first equipment symbolb 704a can comprise a text entered into said 602 which spells out “Equip1” and said split and number symbol 704b can comprise the text “s4”. In one embodiment, said first equipment symbolb 704a and said split and number symbol 704b can be replaced by a symbol or picture of the desired equipment, a voice entry (such as “Equip One” or “Equipment One” spoken to be the equivalent of “Equip1” as entered as text). In one embodiment, a line completion logic can be applied to said process diagram 600 while it is being created. For example, upon tapping said touch point 702 and entering “s4” at said split and number symbol 704b, said process diagram 600 can account for said first split point 608a, a four lines (splitting into four lines from said first split point 608a) and the conclusion of each of said four lines at said one or more end points 604b. Accordingly, said field data capture system 100 can account for the complete design of a system with said line completion logic.

In one embodiment, a new figure can comprise said one or more starting points 604a, said first line 610a and said one or more end points 604b. However, said process diagram 600 can have multiple starting and ending points, as would be obvious to one of ordinary skill in the art.

Here, said SLMS data records 504 can comprise said structured markup language 701 for what is represented on said screen 202 in said process diagram 600; wherein, “SP<604>” represents said one or more starting points 604a, and SP<604>{L<610a>{ } } EP<606>” means that said one or more starting points 604a and said one or more end points 604b are connected by said 610a. Further discussion of said structured markup language 701 shall be minimal as the use of a markup language in this manner is well-known in the art.

Thus, as shown in FIG. 7B, said first equipment symbolb 704a can be rendered as said first equipment 612a and said split and number symbol 704b can be rendered as a four lines (comprising of said second line 610b, said third line 610c, said fourth line 610d and said fifth line 610e) after said first split point 608a.

FIG. 7B illustrates a step of adding another valve to said process diagram 600.

In one embodiment, said touch point 702 can activate said second line 610b, and said first equipment symbolb 704a can be entered into said data entry area 602 again. Accordingly, said second equipment 612b can be added to said second line 610b, as is rendered in FIG. 7C. Likewise, said third equipment 612c can be added to said process diagram 600.

FIG. 7C illustrates a step of adding a new split to said process diagram 600.

In one embodiment, a two or more of said one or more lines can be merged back into one another behind a new split. For example, in one embodiment, said second line 610b and said third line 610c can be selected with said touch point 702 (applied in multiple locations at the same or nearly the same time), and said merger symbol 704c can be entered into said data entry area 602. Accordingly, said structured markup language 701 in said SLMS data records 504 can be updated to put said second line 610b and said third line 610c under a new splitter, said second split point 608b, marked-up as “S<608b>{L<610b>{V<612b>}, L<610c>{V<612c>} }”, as illustrated. Likewise, a new line going into and out of said new split point must be added (here said seventh line 610g is added coming into it and said sixth line 610f is added leaving it).

FIG. 7D illustrates a step of adding another valve below the merged area in said process diagram 600.

Said sixth equipment 612f can be added at said sixth line 610f, as illustrated and using a process similar to that disclosed above.

FIG. 7E illustrates the steps of adding said seventh equipment 612g.

The addition of said fourth equipment 612d and said fifth equipment 612e are not discussed as they will be added according to the procedure explained above. Likewise, other equipment can be added to said process diagram 600, such as said seventh equipment 612g. In one embodiment, said seventh equipment 612g can be added to said process diagram 600 by touching said fifth line 610e with said touch point 702 and drawing said tank symbol 704d in said data entry area 602.

FIG. 7F illustrates said process diagram 600 fully rendered.

In one embodiment, when said process diagram 600 is completed, a user can save his work by entering said finished symbol 704e into said data entry area 602.

In one embodiment, said process diagram 600 can be rendered from a save data in said SLMS data records 504, provided said saved data is in a format suggested by said structured markup language 701. Note, however, that said structured markup language 701 is a suggestion and not a final or preferred embodiment for said field data capture system 100.

FIG. 7G illustrates a detailed part screen 748 for said seventh equipment 612g.

In one embodiment, double tapping on one of said one or more symbols 704 (such as said seventh equipment 612g) can bring a user of said field data capture system 100 to said detailed part screen 748 related to that equipment. In one embodiment, said detailed part screen 748 can comprise an attributes zone 750. In one embodiment, said detailed part screen 748 can be useful for entering one or more attributes 752 (such as a first attribute 752a, a second attribute 752b, a third attribute 752c and a fourth attribute 752d). In one embodiment, said one or more attributes 752 can comprise data related to said seventh equipment 612g (or whichever among said one or more symbols 704 that said detailed part screen 748 has been opened up). In one embodiment, said attributes zone 750 on said screen 202 can display an equipment attributes zone 753, an images zone 754 and a notes zone 756. In one embodiment, said one or more attributes 752 can be listed in said equipment attributes zone 753; wherein, one or more of said equipment attributes zone 753 can be selected from a dropdown list associated with an equipment type (in this case attributes associated with said seventh equipment 612g), and data related to said one or more attributes 752 can be entered into said equipment attributes zone 753. In one embodiment, an icon of said one or more equipment can be updated based on corresponding of said one or more attributes 752, as is known in the art and illustrated below. In one embodiment, a user of said field data capture system 100 can capture an image with said tablet 201c and that image can be stored in said images zone 754 (which can comprise a first image 754a, a second image 754b, and so on). In one embodiment, one or more notes can be stored in said notes zone 756, which can include a voice note 756a and/or a text note 756b. In one embodiment, said tablet 201c can collect said voice note 756a with a microphone, as is known in the art. In one embodiment, said text note 756b can be entered into said tablet 201c by conventional means.

FIGS. 8A and 8B illustrate two flow diagrams as to how said device application 502 can interpret data entered into said data entry area 602.

FIG. 8A illustrates a plurality of interpreting steps 800.

In one embodiment, said device application 502 can comprise said plurality of interpreting steps 800, which can comprise: a first step 802 (comprising receiving said one or more symbols 704); a second step 804 (comprising analyzing said one or more symbols 704); a third step 806 (comprising displaying a match for said one or more symbols 704); a fourth step 808 (comprising receiving a confirmation or rejection of said match); a fifth step 810 (comprising offering to add a multimedia annotation); a sixth step 812 (comprising receiving one or more variables with said one or more symbols 704); a seventh step 814 (comprising updating and saving said SLMS data record); and an eighth step 816 (comprising waiting for more of said one or more symbol). In one embodiment, analyzing said one or more symbols 704 804 can render close matches where a user of said field data capture system 100 does not provide a perfect input at said data entry area 602.

FIG. 8B illustrates a plurality of diagram creation steps 828.

In one embodiment, said plurality of diagram creation steps 828 can comprise: a first step 830 (comprising defining one or more lines between one or more starting points and one or more end points), a second step 832 (comprising receiving a touch point along said one or more lines), a third step 834 (comprising receiving said one or more symbols 704 representing one or more equipment), a fourth step 836 (comprising receiving said one or more symbols 704 representing one or more equipment), a fifth step 838 (comprising placing said one or more equipment on said one or more lines), and a sixth step 840 (comprising updating said structured markup language 701 with a reference to said one or more equipment.

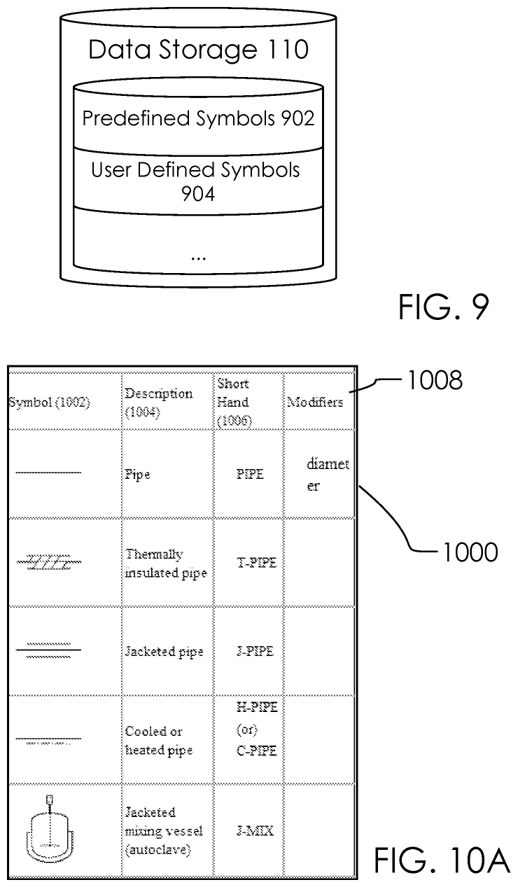

FIG. 9 illustrates a flow diagram view of said data storage 110 comprising said predefined symbols 902 and said user defined symbols 904.

In one embodiment, said predefined symbols 902 can comprise a set of symbols which are common to a plurality of users and said user defined symbols 904 can be set up by individual users and thereafter possibly shared.

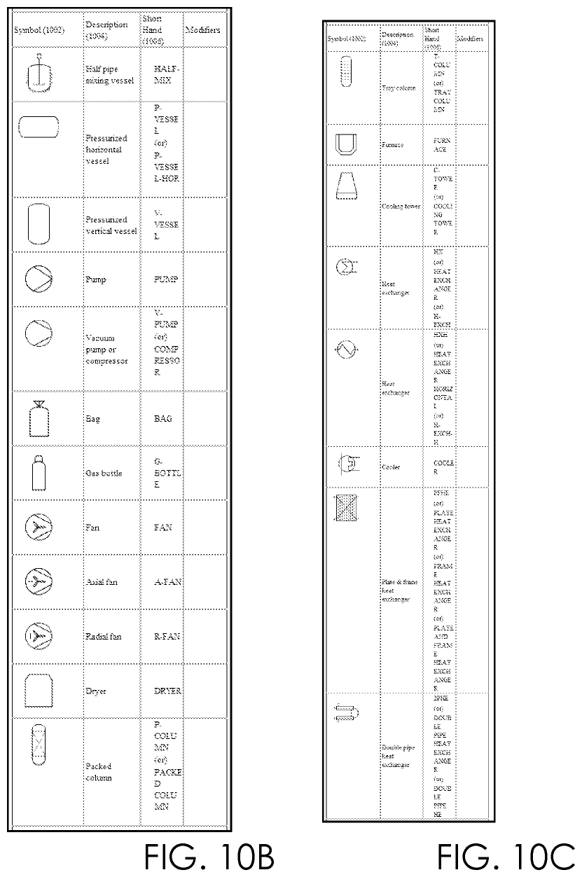

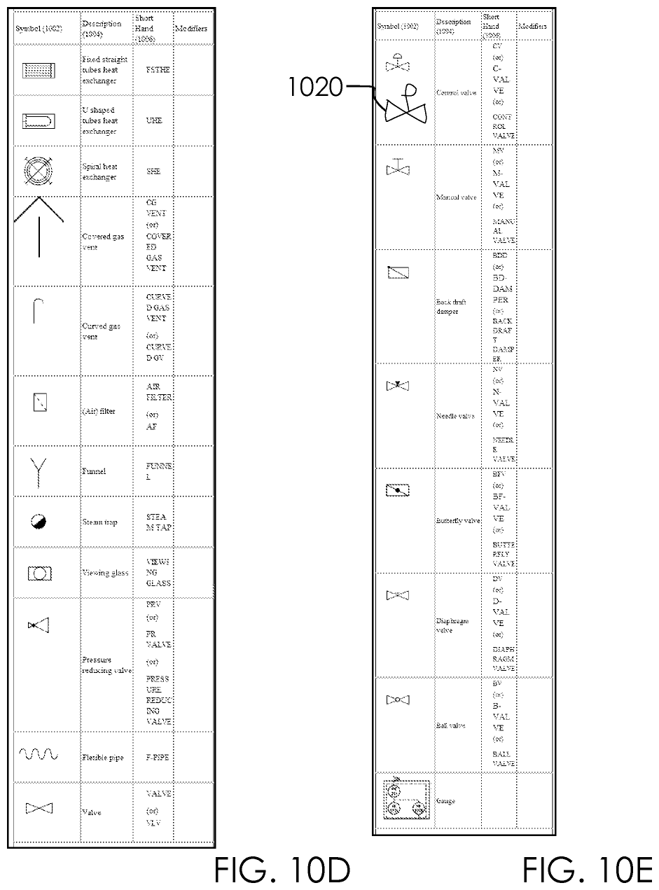

FIGS. 10A, 10B, 10C, 10D and 10E illustrate a table of symbols 1000.

In one embodiment, said table of symbols 1000 is divided up among FIG. 10A-10E as it is too long to fit on one page in one column. In one embodiment, said table of symbols 1000 can comprise said predefined symbols 902 in table form. In one embodiment, said table of symbols 1000 can comprise a symbol icon 1002, a description 1004, a shorthand 1006 and a modifier 1008. In one embodiment, a user can enter text into said data entry area 602 from either said description 1004 and/or said shorthand 1006 and said symbol icon 1002 can be rendered into said process diagram 600 (or another diagram). Likewise, an icon can be drawn (like said symbol icon 1002) which is then interpreted by said field data capture system 100 to be said symbol icon 1002. For example, in one embodiment, (referring to FIG. 10E) a control valve diagram 1020 can be drawn in said data entry area 602 rather than writing “CV” as suggested in said shorthand 1006 for that equipment.

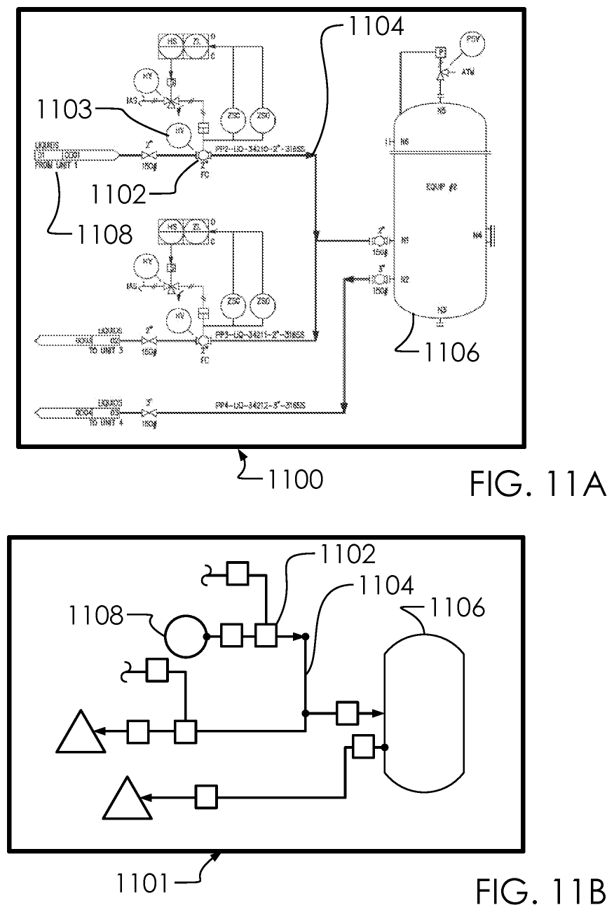

FIGS. 11A and 11B illustrate a rendered P&ID diagram 1100 and a simplified P&ID diagram 1101 (like said process diagram 600).

In one embodiment, said rendered P&ID diagram 1100 can comprise a plurality from among said one or more equipment (such as a valve 1102 and a tank 1106), a plurality from among said one or more lines (such as a first line 1104), one or more input 1108 and one or more outputs 1110; wherein said one or more inputs 1108 and said one or more outputs 1110 direct the dialog on and off of said rendered P&ID diagram 1100. In one embodiment, said rendered P&ID diagram 1100 can be rendered from said simplified P&ID diagram 1101. Likewise, in one embodiment, like said process diagram 600, said simplified P&ID diagram 1101 can be drawn with careful addition of said one or more starting points 604a, said one or more end points 604b, said one or more lines, said one or more equipment, said one or more split points and said and one or more attributes 1103 (similar to said one or more attributes 752, discussed above).

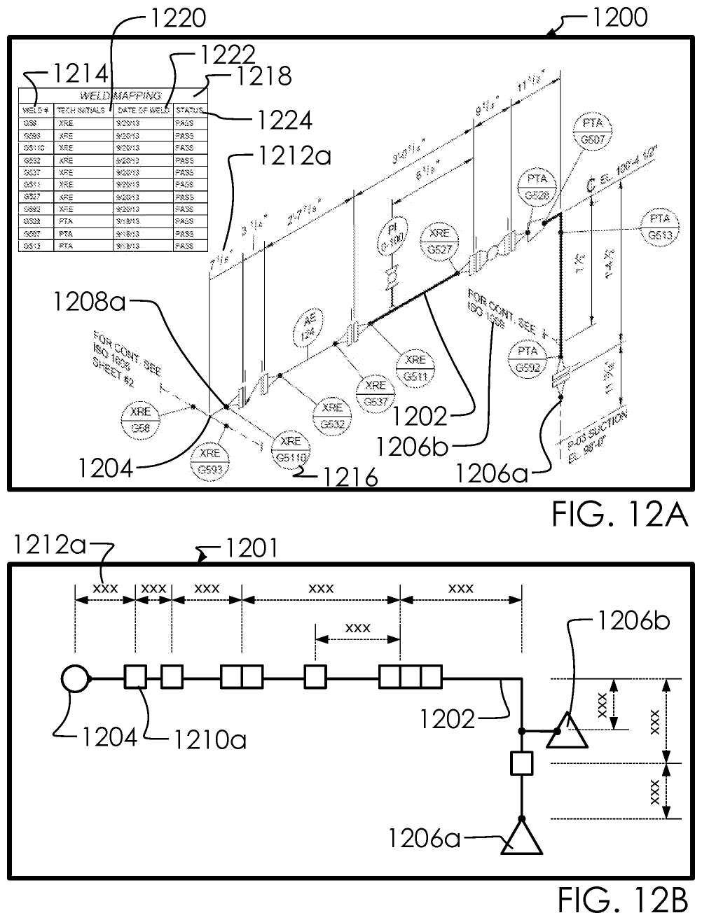

FIGS. 12A and 12B illustrate a rendered weld mapping diagram 1200 and a simplified weld mapping diagram 1201 (like said process diagram 600).

In one embodiment, said rendered weld mapping diagram 1200 can track the quality and status of welds, as is known in the art. In one embodiment, said field data capture system 100 can be used to capture data related to such welds. In one embodiment, said simplified weld mapping diagram 1201 can comprise a starting point 1204, a first end point 1206a, a second end point 1206b, all connected by a line 1202 (representing a pipe). In one embodiment, creating said simplified weld mapping diagram 1201 can comprise tapping said line 1202 and adding said one or more equipment (such as a first equipment 1210a and/or one or more weld points (such as a first weld point 1208a). In one embodiment, said field data capture system 100 can track one or more weld distances (such as a first weld distance 1212a) between said one or more weld points. In one embodiment, each of said one or more weld points can comprise a weld number 1214; for example, said first weld point 1208a can comprise “G58” as said weld number 1214, as illustrated in a call out 1216 and a legend 1218 in said rendered weld mapping diagram 1200. In one embodiment, said field data capture system 100 can track a tech identifier 1220, a date of weld field 1222 and a weld status field 1224.

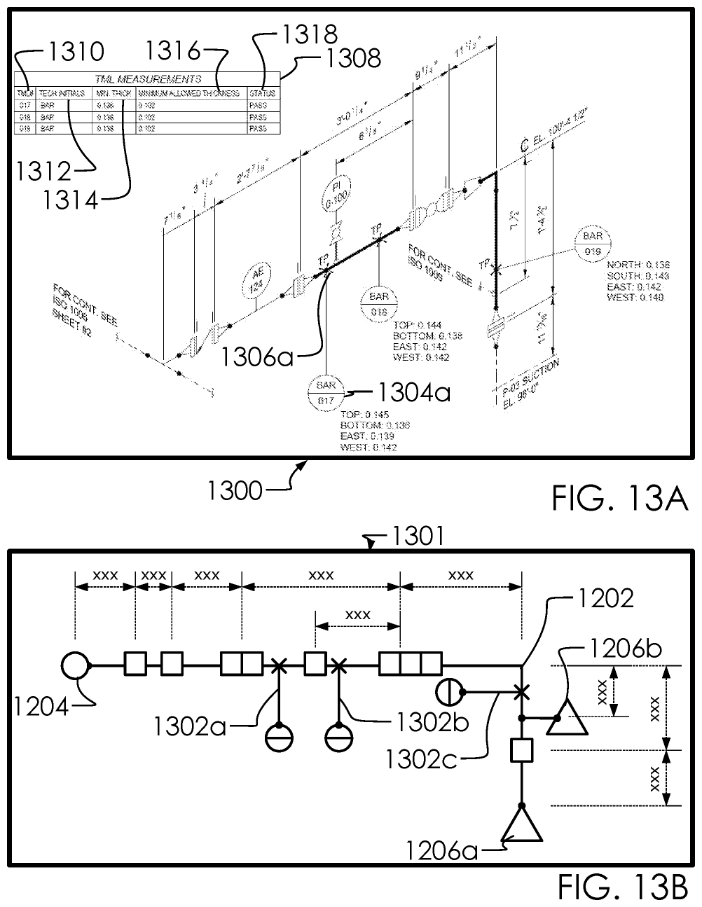

FIGS. 13A and 13B illustrate a rendered pipe status diagram 1300 and a simplified pipe status diagram 1301 (like said process diagram 600).

In one embodiment, said rendered pipe status diagram 1300 can be similar to said rendered weld mapping diagram 1200 but—for the addition of one or more pipe status locations (such as a first pipe status location 1306a) which correspond to one or more pipe status callouts (such as a first pipe status callout 1304a). In one embodiment, said one or more pipe status locations can be added to said simplified pipe status diagram 1301 by tapping said line 1202, entering a pipe status symbol into said data entry area 602, and entering one or more attributes related to said one or more pipe status locations. In one embodiment, said field data capture system 100 can collect one or more TML measurements (represented in said rendered pipe status diagram 1300 as a TML measurement legend 1308) including a TML number 1310, a tech identifier 1312 (similar to said tech identifier 1220), a minimum thickness 1314, a minimum allowed thickness 1316 and a TML status field 1318.

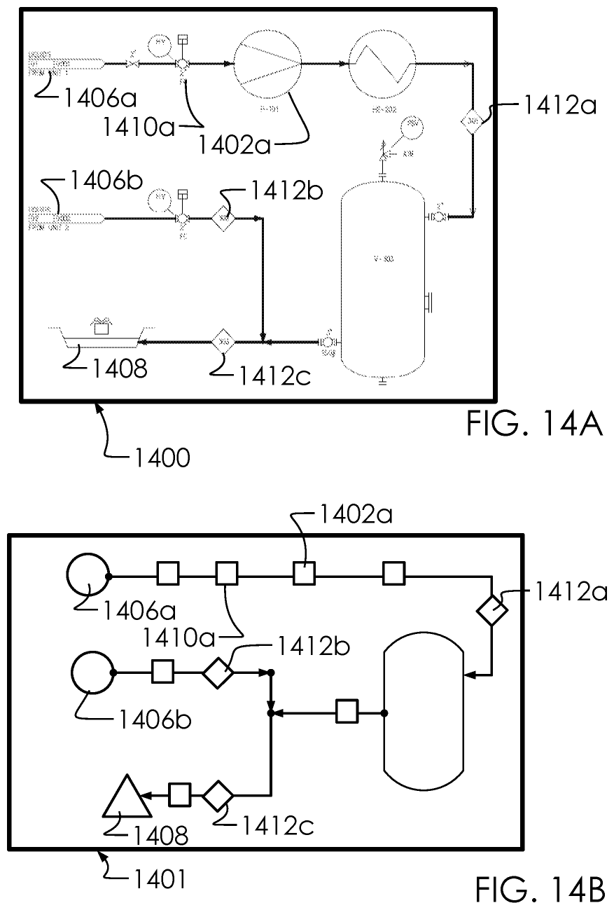

FIGS. 14A and 14B illustrate a rendered PFD diagram 1400 and a simplified PFD diagram 1401 (like said process diagram 600).

In one embodiment, said rendered PFD diagram 1400 can be created by entering in data into said simplified PFD diagram 1401, as will be familiar by now. In one embodiment, said simplified PFD diagram 1401 can comprise a first starting point 1406a, a second starting point 1406b, a first equipment 1410a, one or more PFD elements (such as a first PFD element 1402a), one or more PFD identifiers (such as a first identifier 1412a, a second identifier 1412b and a third identifier 1412c), and an end point 1408.

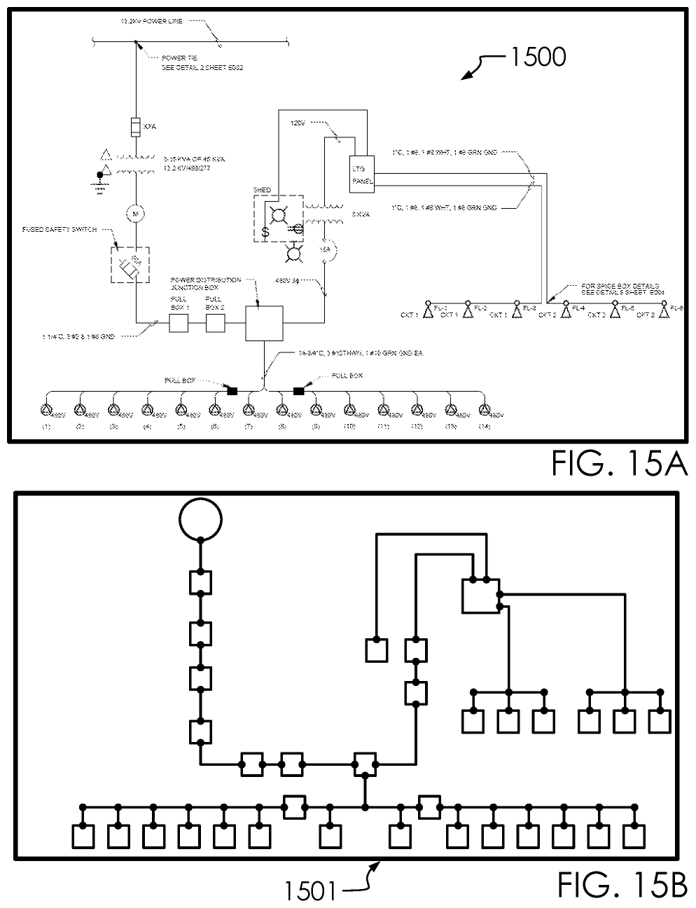

FIGS. 15A and 15B illustrate a rendered electrical diagram 1500 and a simplified electrical diagram 1501.

As will be routine by now, said simplified electrical diagram 1501 can be created by entering data into said field data capture system 100 and rendered by taking such data and rendering according to well-known standards as said rendered electrical diagram 1500.

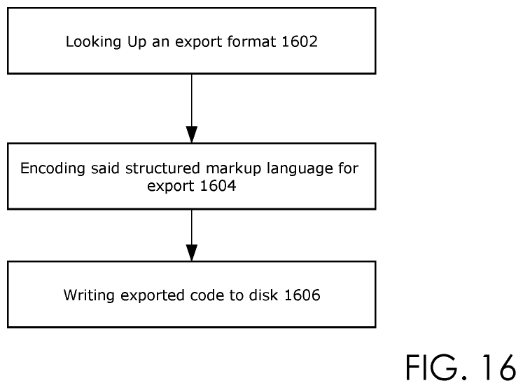

FIG. 16 illustrates a flow diagram for exporting data from said field data capture system 100.

In one embodiment, exporting data from said field data capture system 100 can comprise: a first step 1602 comprising looking up an export format, a second step 1604 comprising encoding said structured markup language for export, and a third step 1606 comprising writing exported code to disk.

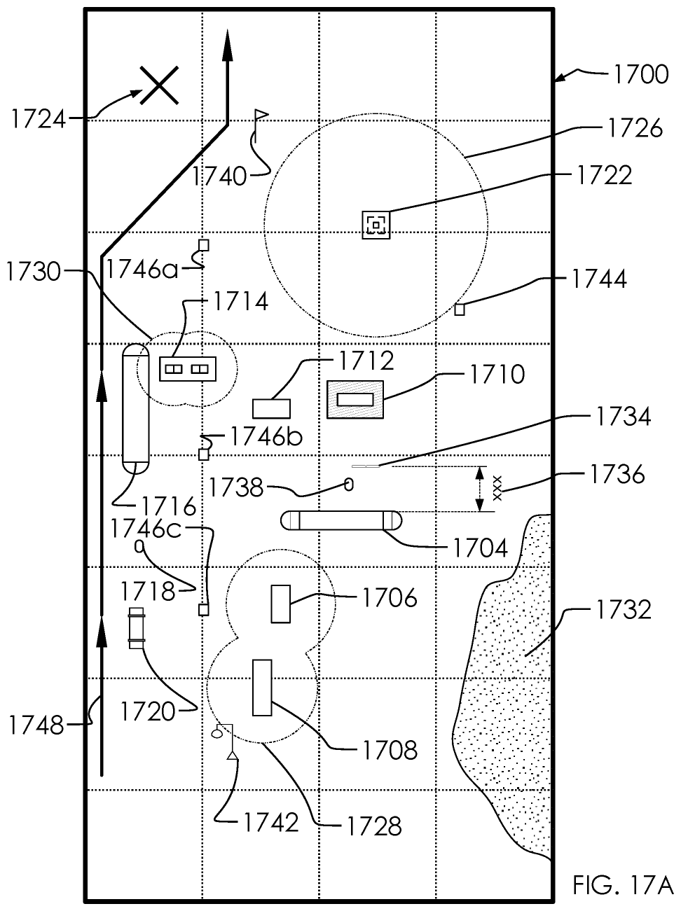

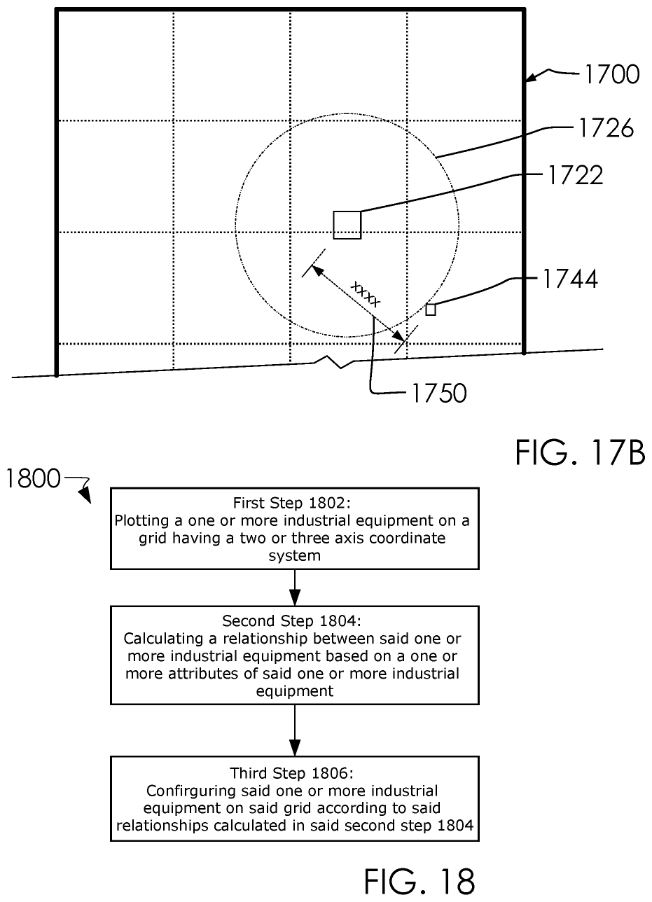

FIGS. 17A and 17B illustrate two elevated overviews of an industrial layout diagram 1700.

In one embodiment, said device application can be configured to capture and markup said industrial layout diagram 1700. In one embodiment, said industrial layout diagram 1700 can be illustrated on a grid 1702. In one embodiment, said industrial layout diagram 1700 can comprise a slug catcher 1704, an amine rundown tanks 1706, a filter skid 1708, a CO2 Vent Knockdown Tanks 1710, a HMO Heater 1712, a product pump skids 1714, an inlet gas separator 1716, a fuel gas contactors 1718, a residue skid 1720, a flare vent stack 1722, an assembly point 1724, an equipment warning area 1726, a first noise warning area 1728, a second noise warning area 1730, a weed control area 1732, an isolation valve 1734, a distance measurement 1736, an emergency shutdown device 1738, a wind sock 1740, a shower 1742, a fire hydrant 1744, one or more flood lights (such as a first light 1746a, a second light 1746b, and a third light 1746c), and an evacuation route 1748.

In one embodiment, said field data capture system 100 can provide said grid 1702 when said industrial layout diagram 1700 is activated. Wherein, one or more industrial equipment can be laid out according to an x-axis and y-axis location. In another embodiment, a z-axis can be provided for non-flat surfaces, but for the purposes of this illustration a flat (2D) surface is provided.

Said one or more industrial equipment can have special characteristics. For example, in one embodiment, said flare vent stack 1722 can have said equipment warning area 1726 which can comprise a radius within which no other equipment may be placed. Similarly, said first noise warning area 1728 can surround said amine rundown tanks 1706 and said filter skid 1708. Accordingly, as more among said one or more industrial equipment are placed upon said grid 1702, said field data capture system 100 can calculate the placement and limitations of other equipment placed thereupon. Likewise, a minimum density of said one or more flood lights may be calculated and said one or more flood lights can be automatically added to said grid 1702, as would be understood in the art. Accordingly, said one or more industrial equipment can each have attributes associated with them such as a safety radius (e.g., equipment warning area 1726) or other attributes as would be understood and known in the art. In one embodiment, said one or more industrial equipment can be stored in said field data capture system 100 in said predefined symbols 902 and/or said user defined symbols 904.

Likewise, said field data capture system 100 can calculate a safe and efficient use of surface area within said grid 1702 by reconfiguring said one or more industrial equipment to maximize use of said surface area.

In one embodiment, said one or more attributes of said one or more industrial equipment can correlate with a government standard (such as OCIA requirements).

In one embodiment, said industrial layout diagram 1700 can define one or more noise buffer zones (such as said first noise warning area 1728 and said second noise warning area 1730). For example, in one embodiment, said first noise warning area 1728 can be defined by a 20 dB noise zone.

FIG. 17B illustrates a portion of said industrial layout diagram 1700 at a stage where said flare vent stack 1722 is being added to said grid 1702.

In one embodiment, said field data capture system 100 can ensure that pairs of sets of said one or more industrial equipment are closely associated with one another. For example, in one embodiment, said flare vent stack 1722 requires that said fire hydrant 1744 be installed within a defined radius 1750 thereof, or said shower 1742 be proximate another among said one or more industrial equipment.

FIG. 18 illustrates a flow diagram of a plurality of plotting steps 1800.

In one embodiment, said device application can be configured to execute said plurality of plotting steps. In one embodiment, said plurality of plotting steps 1800 can comprise: a first step 1802 (comprising plotting one or more industrial equipment on a grid having a two or three axis coordinate system), a second step 1804 (comprising calculating a relationship between said one or more industrial equipment based on one or more attributes of said one or more industrial equipment), and a third step 1806 (comprising calculating a relationship between said one or more industrial equipment based on one or more attributes of said one or more industrial equipment).

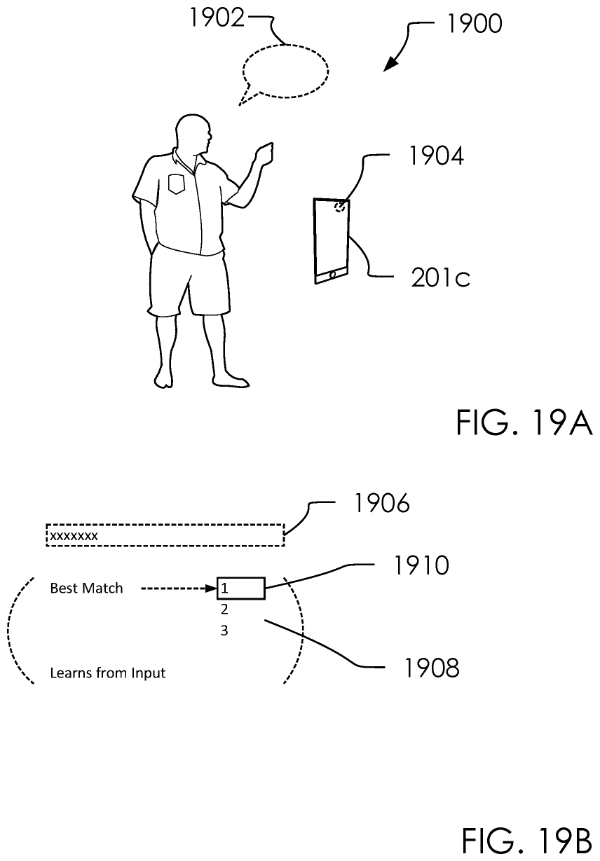

FIGS. 19A, and 19B illustrate a voice to equipment use scenario 1900 of said field data capture system 100 and a flow chart of matching voice inputs to data in said device application 502.

In one embodiment, said field data capture system 100 can be configured for receiving a spoken input 1902 through a microphone 1904 on said one or more computers 102, converting said spoken input 1902 in to a digital text transcription 1906, matching said digital text transcription 1906 with one or more proposed matches 1908, matching said digital text transcription 1906 with a best match 1910 among said one or more proposed matches 1908, and creating said one or more equipment 612 for use in said device application 502.

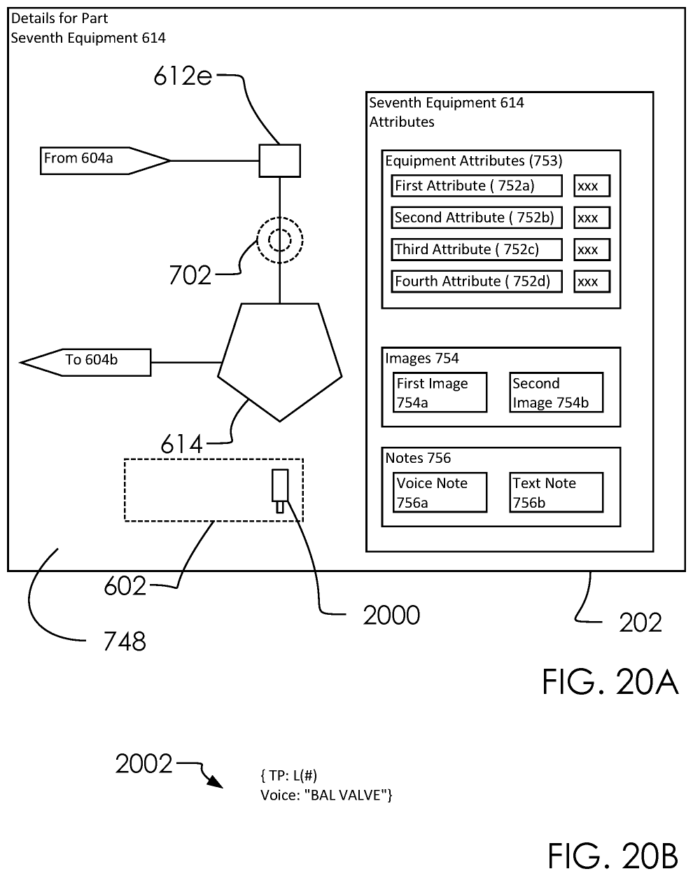

FIGS. 20A, and 20B illustrate said detailed part screen 748 with a microphone icon 2000.

In one embodiment, a GUI of said device application 502 can comprise said microphone icon 2000 which can be located in said data entry area 602. Said device application 502 can be configured to receive said touch point 702 and said microphone icon 2000, collecting said spoken input 1902, and proceeding to create said one or more proposed matches 1908 as discussed above. Said device application 502 can be configured, thereby, to create a location and equipment entry 2002 for said process diagram 600.

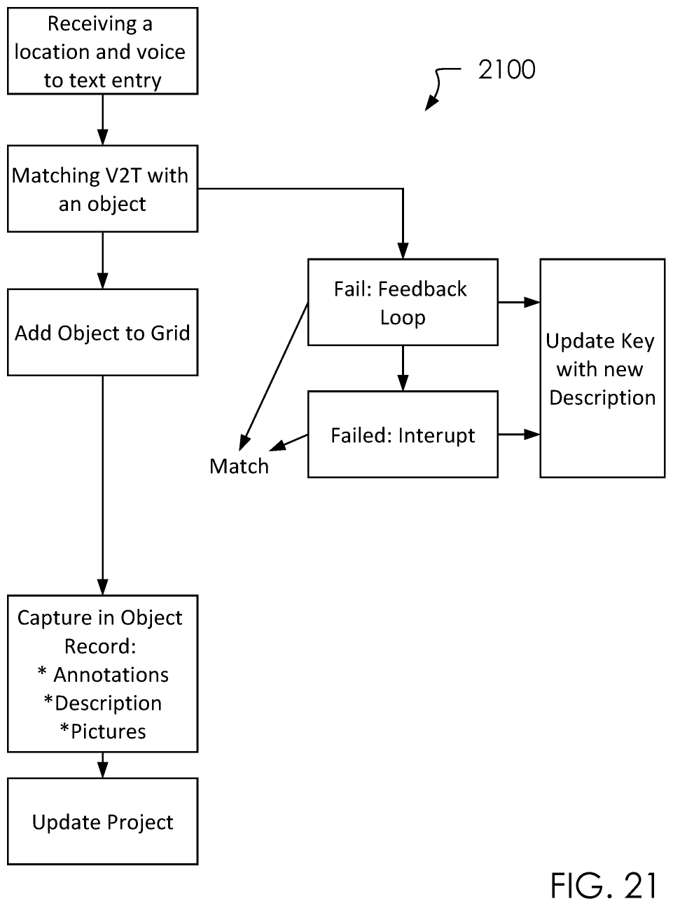

FIG. 21 illustrates a voice to equipment flow chart 2100.

In one embodiment, said device application 502 can be configured for receiving said touch point 702 on said process diagram 600, receiving said spoken input 1902, creating said digital text transcription 1906 from said spoken input 1902, filtering a database of equipment to said one or more proposed matches 1908, proposing said best match 1910 among said one or more proposed matches 1908 based on said spoken input 1902, creating said one or more equipment 612 based on said best match 1910. In one embodiment, said device application 502 can be further configured for gathering one or more new matching terms 2102 and updating a term and equipment cross reference table 2104 based on interactions between said device application 502 and end users.

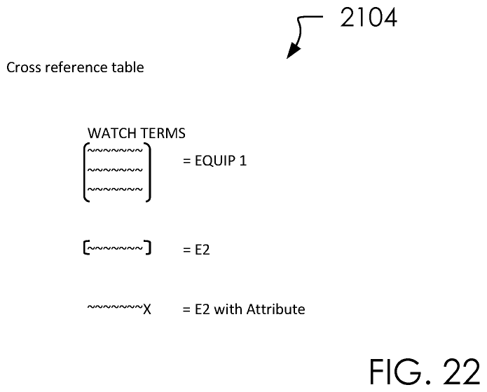

FIG. 22 illustrates said term and equipment cross reference table 2104 and said one or more new matching terms 2102.

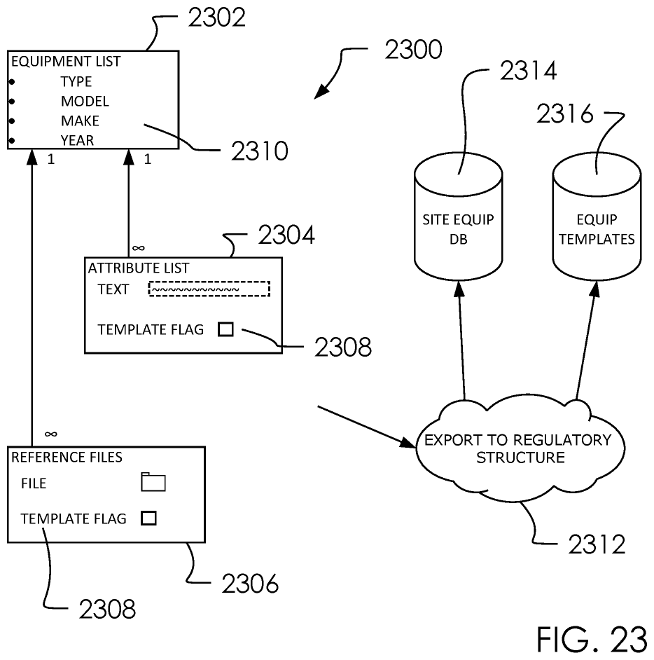

FIG. 23 illustrates an equipment data collection diagram 2300.

In one embodiment, said device application 502 can be configured to collecting an equipment list 2302 comprising a list of said one or more equipment 612 used at a project, each unique entry into said equipment list 2302 can comprise a sublist (one to many) comprising an attribute list 2304 and a reference files list 2306. In one embodiment, each entry into said attribute list 2304 and or said reference files list 2306 can comprise a template flag 2308 indicating that a particular attribute and/or file is applicable to all equipment of the type listed in said equipment list 2302.

In one embodiment, said equipment list 2302 can comprise one or more general attributes 2310 such as make, model, year and type of equipment.

In one embodiment, said device application 502 can comprise an exporting module 2312 configured for collecting attributes and files for each piece of equipment at a project and exporting them to a site equipment database 2314. Likewise, said exporting module 2312 can be configured for collecting all attributes and reference files with said template flag 2308 selected and updating an equipment template database 2316 for each unique equipment type as defined by said one or more general attributes 2310.

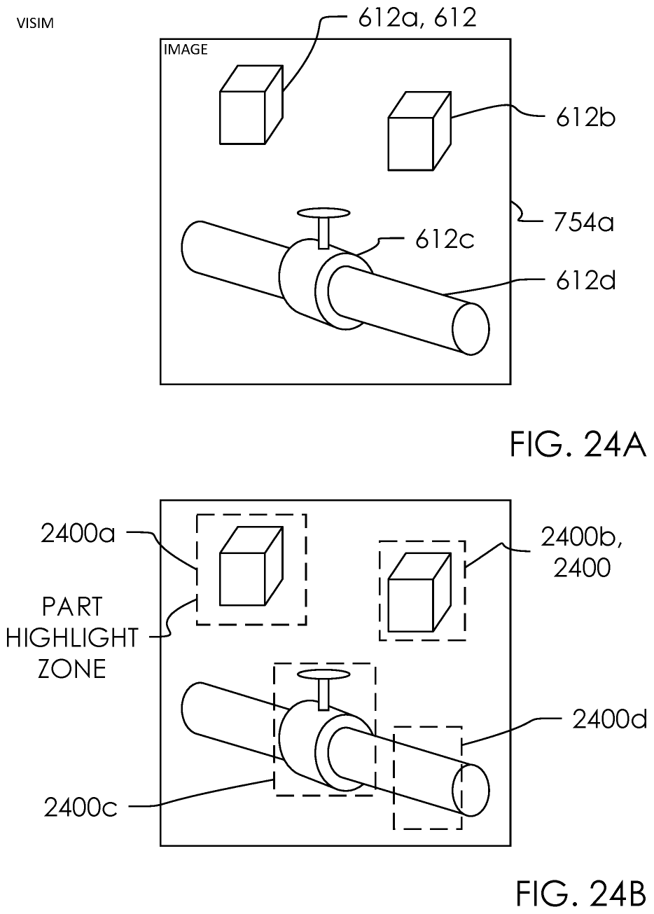

FIGS. 24A, and 24B illustrate said first image 754a and said first image 754a with one or more hyperlinked zones 2400, respectively.

As illustrated, said first image 754a comprises images of said first equipment 612a, said second equipment 612b, said third equipment 612c and said fourth equipment 612d. In one embodiment, said one or more hyperlinked zones 2400 can comprise comprise a first hyperlinked zones 2400a, a second hyperlinked zones 2400b, a third hyperlinked zones 2400c, and a fourth hyperlinked zones 2400d.

Said device application 502 can be configured to add said one or more hyperlinked zones 2400 as an overlay layer over said one or more equipment 612, and link said one or more hyperlinked zones 2400 items in said equipment list 2302.

Various changes in the details of the illustrated operational methods are possible without departing from the scope of the following claims. Some embodiments may combine the activities described herein as being separate steps. Similarly, one or more of the described steps may be omitted, depending upon the specific operational environment the method is being implemented in. It is to be understood that the above description is intended to be illustrative, and not restrictive. For example, the above-described embodiments may be used in combination with each other. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.”

1. A field data capture system comprising:
one or more computers comprising of a first computers having a processor, a memory, a communication hardware and a data storage;
said first computers capable of storing and modifying a SLMS data records;
a device application stored in said memory and execute in said processor of said first computers;
said device application is configured for receiving, modifying and storing as an SLMS data records of an input of one or more starting points, one or more lines, one or more equipment arranged on said one or more lines, and one or more end points;
said device application is configured for
receiving one or more symbols,
analyzing said one or more symbols,
displaying a match for said one or more symbols,
receiving a confirmation or rejection of said match,
receiving one or more variables with said one or more symbols,
updating and saving said SLMS data record, and
waiting for more of said one or more symbols;
said device application is further configured for offering to add a multimedia annotation prior to updating said SLMS data record;
analyzing said one or more symbols is configured to render close matches where a user of said field data capture system does not provide a perfect input at a data entry area;
said device application further comprises a plurality of diagram creation steps comprising
defining said one or more lines between said one or more starting points and said one or more end points,
receiving a touch point along said one or more lines,
receiving said one or more symbols representing said one or more equipment,
receiving said one or more symbols representing said one or more equipment,
placing said one or more equipment on said one or more lines, and
updating a structured markup language with a reference to said one or more equipment.

2. A field data capture system comprising:
one or more computers comprising of a first computers having a processor, a memory, a communication hardware and a data storage;
said first computers capable of storing and modifying a SLMS data records;
a device application stored in said memory and execute in said processor of said first computers; and
said device application is configured of receiving, modifying and storing as an SLMS data records of an input of one or more starting points, one or more lines, one or more equipment arranged on said one or more lines, and one or more end points.

3. The field data capture system of claim 2 wherein:
The SLMS data records are stored as a structured markup language in said data storage.

4. The field data capture system of claim 2 wherein:
entering The one or more equipment into said field data capture system comprises:
touching one of said one or more lines;
entering one or more symbols into a data entry area on a screen of said first computers;
matching said one or more symbols with a symbol icon or a description from a table of symbols in said data storage;
writing a corresponding markup label to said structured markup language; and
rendering said symbol icon on a process diagram.

5. The field data capture system of claim 2 wherein:
The one or more equipment each one or more attributes; further wherein,
defining said one or more attributes comprises:
selecting one among said one or more equipment on said first computers,
selecting one or more among said one or more attributes in an equipment attributes zone on said field data capture system, and
entering said one or more attributes for said one among said one or more equipment.

6. The field data capture system of claim 2 wherein:
The data storage further comprises one or more images of said one or more equipment.

7. The field data capture system of claim 2 wherein:
entering The one or more equipment into said field data capture system comprises:
touching one of said one or more lines;
speaking said description of said one or more equipment into a microphone of said first computer;
converting a spoken description into a text description;
matching said text description with said symbol icon or said description from said table of symbols in said data storage;
writing a corresponding markup label to said structured markup language; and
rendering said symbol icon on a diagram.

8. The field data capture system of claim 2 wherein:
The table of symbols comprise symbols characterized for use among a P&ID diagram, a PFD diagram, a weld mapping diagram, an electrical diagram, an ultrasonic thickness location diagram and a plot plan diagram.

9. The field data capture system of claim 2 wherein:
The device application is configured for
receiving said one or more symbols,
analyzing said one or more symbols,
displaying a match for said one or more symbols,
receiving a confirmation or rejection of said match,
receiving one or more variables with said one or more symbols,
updating and saving said SLMS data record, and
waiting for more of said one or more symbol.

10. The field data capture system of claim 9 wherein:
The device application is further configured for offering to add a multimedia annotation prior to updating said SLMS data record.

11. The field data capture system of claim 9 wherein:
analyzing The one or more symbols is configured to render close matches where a user of said field data capture system does not provide a perfect input at said data entry area.

12. The field data capture system of claim 9 wherein:
The device application further comprises a plurality of diagram creation steps comprising:
defining said one or more lines between said one or more starting points and said one or more end points,
receiving a touch point along said one or more lines,
receiving said one or more symbols representing said one or more equipment,
receiving said one or more symbols representing said one or more equipment,
placing said one or more equipment on said one or more lines, and
updating said structured markup language with a reference to said one or more equipment.

13. The field data capture system of claim 9, wherein:
The device application is configured to execute a plurality of plotting steps comprising:
plotting one or more industrial equipment on a grid having a two or three axis coordinate system,
calculating a relationship between said one or more industrial equipment based said one or more attributes of said one or more industrial equipment, and
calculating a relationship between said one or more industrial equipment based said one or more attributes of said one or more industrial equipment;
said device application is configured to capture and markup an industrial layout diagram using said plurality of plotting steps;
said industrial layout diagram is illustrated on said grid;
said grid can comprise a 2D or 3D rendering of an industrial setting;
one or more industrial equipment are arranged on said grid; and
said one or more industrial equipment are configured to have one or more special characteristics according to which, as each among said one or more industrial equipment is placed upon said grid, said device application is configured to calculate the placement and limitations of other equipment placed thereupon.

14. The field data capture system of claim 13, wherein:
said one or more special characteristics comprise equipment warning area which comprises a radius within which no other equipment may be placed.

15. The field data capture system of claim 13, wherein:
said one or more special characteristics comprise a noise warning area around a portion of said one or more industrial equipment.

16. The field data capture system of claim 13, wherein:
said one or more special characteristics comprise a minimum density of said one or more flood lights may be calculated and said one or more flood lights is automatically added to The grid.

17. A method for capturing a field data using A field data capture system comprising:
creating a diagram with a device application by
defining one or more lines between one or more starting points and one or more end points,
receiving a touch point along said one or more lines,
receiving one or more symbols representing one or more equipment,
placing said one or more equipment on said one or more lines, and
updating a structured markup language with a reference to said one or more equipment;
wherein receiving said one or more symbols comprises
receiving said one or more symbols using said device application,
analyzing said one or more symbols to render close matches where a user of said field data capture system does not provide a perfect input at a data entry area;
displaying a match for said one or more symbols,
receiving a confirmation or rejection of said match,
receiving one or more variables with said one or more symbols,
updating and saving a SLMS data record, and
waiting for more of said one or more symbols;
wherein said field data capture system one or more computers comprising of a first computer having a processor, a memory, a communication hardware and a data storage;
a first computers capable of storing and modifying a SLMS data records;
said device application stored in said memory and execute in said processor of said first computer; and
said device application is configured of receiving, modifying and storing as an SLMS data records of an input of said one or more starting points, said one or more lines, said one or more equipment arranged on said one or more lines, and said one or more end points.
